(19) United States
(12) Patent Application Publication
(10) Pub. No.: US 2011/0088438 A1
(43) Pub. Date: Apr. 21, 2011

(54) LOW-POWER-CONSUMPTION ACTUATOR FOR BATTERY-POWERED ELECTRONIC LOCK

(75) Inventor: Ti CHEN, Taipei City (TW)

(73) Assignee: Ti CHEN, Taipei City (TW)

(21) Appl. No.: 12/581,897

(22) Filed: Oct. 20, 2009

(51) Int. Cl. E05B 49/02; H01L 41/04

(52) U.S. Cl. 70/278.7; 310/330

(57) ABSTRACT

A low-power-consumption actuator for battery-powered electronic lock includes assembled first and second cases, the second case being provided at a top with a through bore; a piezoceramic/steel sheet assembly consisting of superposed first and second piezoceramic/steel sheet sets, a first end portion of the second piezoceramic/steel sheet set being in a free state; a circuit board electrically connected to the piezoceramic/steel sheet assembly; and a pin unit being located between a top of the first end portion of the second piezoceramic/steel sheet set and the through bore. When the circuit board applies a voltage across the piezoceramic/steel sheet assembly, the first end portion of the second piezoceramic/steel sheet set upward flexes and thereby displaces to push against the pin unit for a pin thereof to protrude from the through bore and interfere with a latch bolt of the electronic lock, so as to actuate the latch bolt.

### FIELD OF THE INVENTION

The present invention relates to an actuator, and more particularly, to a low-power-consumption actuator for a battery-powered electronic lock.

### BACKGROUND OF THE INVENTION

An electronic lock is electrically controlled to extend or retract a latch bolt thereof, so as to lock or unlock the electronic lock.

According to the actuating manner thereof, the currently available electronic lock actuators can be generally divided into two types, namely, a motor transmission type, in which a motor rotor rotates to actuate the latch bolt via gears, and a solenoid or electromagnetic valve type, in which electromagnetic coils are used to produce magnetic force for controlling a projected shaft to activate the latch bolt.

Both of the two types of conventional electronic lock actuators use coils to produce sufficient magnetic force, and therefore require relatively large current and high voltage to drive them to work. Thus, the conventional electronic lock actuators obviously have higher power consumption. For example, the motor or the solenoid being used in the currently available electronic lock actuators usually require at least a current larger than 100 mA and a voltage higher than DC 6V to drive the coils. In the case of a currently available home electronic lock that is powered by four 1.5V batteries, a user might need to replace the batteries once a month. Therefore, the conventional electronic lock actuators are highly power-consuming and not environment-friendly, and not suitable for use in a direct current (DC) environment. Further, for the conventional electronic lock actuators to maintain their required driving power, the solenoid and the whole actuating structure thereof usually occupy a very large volume, which forms a hindrance to the requirement for low-profile and miniaturized products. Further, the motor often produces noise when it drives the gears to rotate.

### SUMMARY OF THE INVENTION

A primary object of the present invention is to provide a low-power-consumption actuator for a battery-powered electronic lock, which provides the advantages of low power consumption, extended service life, reduced volume, and producing no noise.

To achieve the above and other objects, the low-power-consumption actuator for a battery-powered electronic lock according to the present invention includes a housing assembled from a first case and a second case to define a receiving space between the first and the second case, and the second being provided on a top with a through bore; a piezoceramic/steel sheet assembly being arranged in the receiving space, and including two superposed first and second piezoceramic/steel sheet sets, the first piezoceramic/steel sheet set including two opposing first and second end portions with the first end portion fixed to an inner wall surface of the first case, the second piezoceramic/steel sheet set being located on one face of the first piezoceramic/steel sheet set facing toward the second case, and including two opposing first and second end portions, the second end portion of the second piezoceramic/steel sheet set being connected to the second end portion of the first piezoceramic/steel sheet set, and the first end portion of the second piezoceramic/steel sheet set being separated from the first end portion of the first piezoceramic/steel sheet set and in a free state; a circuit board being arranged in the receiving space and fixed to an inner wall surface of the second case, and being electrically connected to the piezoceramic/steel sheet assembly; and a pin unit including a pin and a spring fitted around the pin, the pin being located atop the first end portion of the second piezoceramic/steel sheet set to align with the through bore on the second case and including a shank and an expanded head integrally formed at one end of the shank, and the spring being fitted around the shank of the pin to locate between the expanded head of the pin and an area of the inner wall surface of the second case around a bottom of the through bore. When a latch bolt of the electronic lock is in an extended position and the electronic lock is in a locked state, and it is desired to unlock the electronic lock, a voltage can be applied by the circuit board across the piezoceramic/steel sheet assembly, so that the first end portion of the second piezoceramic/steel sheet set in the free state upward flexes to produce displacement and accordingly, pushes against the pin of the pin unit. At this point, the pin is protruded from the through bore on the second case and the whole actuator can be translated or rotated to interfere with and actuate the latch bolt of the electronic lock.

According to an embodiment of the present invention, the first and the second piezoceramic/steel sheet set respectively includes stacked steel sheet, ceramic layer, and conductive metal layer. The steel sheets serve as permanent elastic bodies, and are spaced from the conductive metal layers by the ceramic layers. By applying a high voltage across the conductive metal layers and the steel sheets, the ceramic molecule structure in the ceramic layers is changed to shrink the ceramic layers, which brings the steel sheet of the second piezoceramic/steel sheet set to flex and produce displacement.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a partially exploded perspective view of a low-power-consumption actuator for battery-powered electronic lock according to a preferred embodiment of the present invention;

FIG. 2 is a fully exploded perspective view of FIG. 1;

FIG. 3 is a sectional view taken along line A-A of FIG. 2;

FIG. 4 is a sectional view taken along line B-B of FIG. 2;

FIG. 5 is an assembled sectioned side view of the low-power-consumption actuator for battery-powered electronic lock of FIG. 1 when no current is supplied thereto;

FIG. 6 is an assembled sectioned side view of the low-power-consumption actuator for battery-powered electronic lock of FIG. 1 when a current is supplied thereto;

FIG. 7 shows the application of the low-power-consumption actuator of the present invention to an electronic lock; and

FIG. 8 shows the application of the low-power-consumption actuator of the present invention to a standard electronic door lock.

### DETAILED DESCRIPTION OF THE PREFERRED EMBODIMENTS

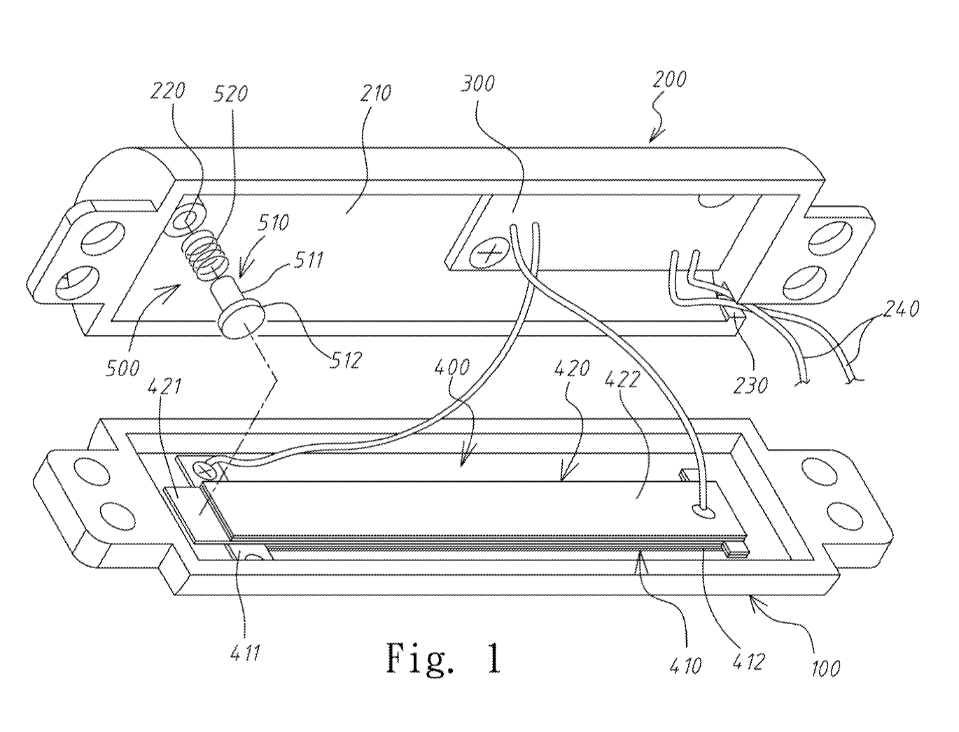

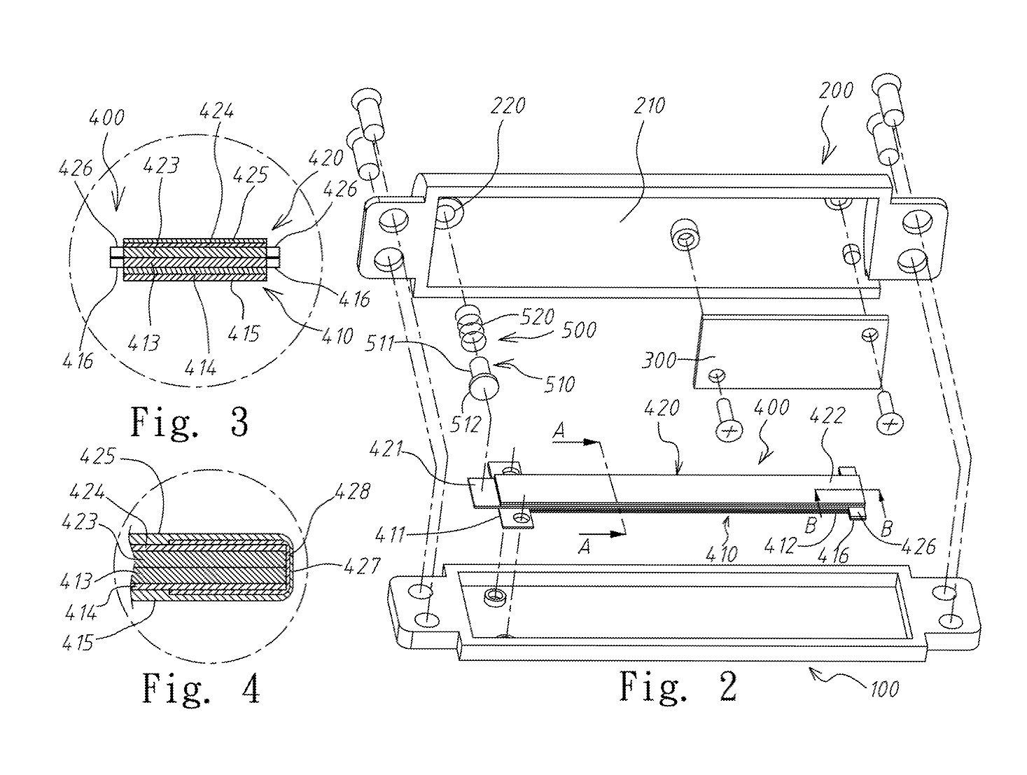

Please refer to FIGS. 1 and 2 that are partially and fully exploded perspective views, respectively, of a low-power-consumption actuator for battery-powered electronic lock according to a preferred embodiment of the present invention. For the purpose of conciseness, the present invention is also briefly referred to as “the actuator” herein. As shown, the actuator in the preferred embodiment of the present invention includes a first case 100, a second case 200, a circuit board 300, a piezoceramic/steel sheet assembly 400, and a pin unit 500.

The first case 100 and the second case 200 are assembled to each other to form a semi-cylindrical housing, in which a receiving space 210 is defined. With the semi-cylindrical housing, the actuator can be conveniently translated or rotated. The second case 200 is provided at a predetermined position on a top thereof with a through bore 220, which communicates the receiving space 210 with an outer side of the actuator, and at another position with a notch 230 that extends through a wall of the second case 200, so that a power cord 240 can be extended therethrough into the receiving space 210 and electrically connected to the circuit board 300.

The piezoceramic/steel sheet assembly 400 is arranged in the receiving space 210 between the first and the second case 100, 200, and includes two superposed first and second piezoceramic/steel sheet sets 410, 420. The first piezoceramic/steel sheet set 410 has a first end portion 411 fixed to an inner wall surface of the first case 100 and an opposing second end portion 412. The second piezoceramic/steel sheet set 420 is located on one face of the first piezoceramic/steel sheet set 410 facing toward the second case 200, and also has a first end portion 421 and an opposing second end portion 422. The second end portion 422 of the second piezoceramic/steel sheet set 420 is welded to the second end portion 412 of the first piezoceramic/steel sheet set 410, while the first end portion 421 of the second piezoceramic/steel sheet set 420 is in a free state separated from the first end portion 411 of the first piezoceramic/steel sheet set 410.

Please refer to FIG. 3 that is a sectional view taken along line A-A of FIG. 2. As shown, the first piezoceramic/steel sheet set 410 includes stacked first steel sheet 413, first ceramic layer 414, and first electrically conductive metal layer 415; and the second piezoceramic/steel sheet set 420 includes stacked second steel sheet 423, second ceramic layer 424, and second electrically conductive metal layer 425. In practical implementation of the present invention, the ceramic layer 414, 424 can be formed by, for example, directly spraying or coating a ceramic material on one face of the steel sheet 413, 423. Alternatively, the ceramic layer 414, 424 can be formed by gluing a sheet-shaped ceramic material on one face of the steel sheet 413, 423. The conductive metal layer 415, 425 can be, for example, copper foil glued to one face of the ceramic layer 414, 424 opposite to the steel sheet 413, 423 using a conducting paste to possess good electric conductivity. For each of the first and second piezoceramic/steel sheet sets 410, 420, the steel sheet 413, 423 serves as a permanent elastic body and is spaced from the conductive metal layer 415, 425 by the ceramic layer 414, 424. Whereby when a high voltage about 180˜250V is input from the circuit board 300, which is a boost circuit board, to the conductive metal layers 415, 425 and the steel sheets 413, 423, the ceramic molecule structure in the ceramic layers 414, 424 is changed to shrink the ceramic layers 414, 424, bringing the second steel sheet 423 to flex and generate displacement at the first end portion 411, which is in a free state.

In implementing the present invention, the second end portions 412, 422 of the first and the second piezoceramic/steel sheet set 410, 420, respectively, can be connected to each other by welding the second steel sheet 423 at the second end portion 422 of the second piezoceramic/steel sheet set 420 to the first steel sheet 413 at the second end portion 412 of the first piezoceramic/steel sheet set 410. Alternatively, in an operable embodiment of the present invention, a pair of second lugs 426 is provided two lateral sides of the second steel sheet 423 at the second end portion 422 of the second piezoceramic/steel sheet set 420, and a pair of first lugs 416 is provided to two lateral sides of the first steel sheet 413 at the second end portion 412 of the first piezoceramic/steel sheet set 410 corresponding to the pair of second lugs 426, and the first and the second steel sheet 413, 423 are welded together at the first and the second lugs 416, 426.

Please refer to FIG. 4 that is a sectional view taken along line B-B of FIG. 2. Areas of the first conductive metal layer 415 and the second conductive metal layer 425 at the second end portions 412, 422 of the first and the second piezoceramic/steel sheet set 410, 420, respectively, are bent to connect to each other and thereby form a wrapped end section 427 of the piezoceramic/steel sheet assembly 400. Further, an insulating layer 428 is provided between the wrapped end section 427 and the first steel sheet 413 and the second steel sheet 423 at the second end portions 412, 422 to avoid any polarity contact between the conductive metal layers 415, 425 and the steel sheets 413, 423.

The circuit board 300 is arranged in the receiving space 210 between the first and the second case 100, 200, and is fixed to an inner wall surface of the second case 200. The circuit board 300 is electrically connected to the piezoceramic/steel sheet assembly 400 by, for example, electrically connecting to the steel sheets 413, 423 and the conductive metal layers 415, 425. The circuit board 300 has a boost structure, which can, for example, boost an input voltage of 3V˜6.8V to about 180V˜250V, which is sufficient to displace the second piezoceramic/steel sheet set 420 by a distance larger than 3 mm.

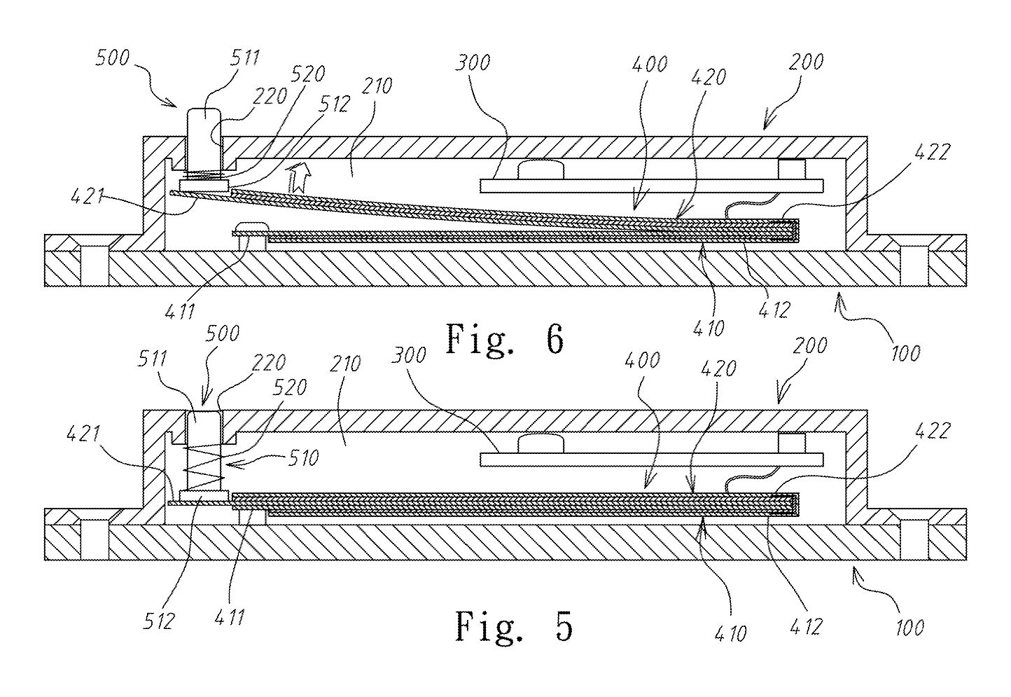

The pin unit 500 includes a pin 510 and a spring 520 fitted around the pin 510. The pin 510 is located atop the first end portion 421 of the second piezoceramic/steel sheet set 420 to align with the through bore 220 on the second case 200. The pin 510 includes a shank 511 and an expanded head 512 integrally formed at one end of the shank 511. The spring 520 is fitted around the shank 511 of the pin 510 to locate between the expanded head 512 of the pin 510 and an area of the inner wall surface of the second case 200 around a bottom of the through bore 220, such that the spring 520 normally pushes the pin 510 rearward for the pin 510 to retract into the through bore 220 when no current is supplied to the actuator, as shown in FIG. 5.

Please also refer to FIG. 7 that shows the actuator according to the preferred embodiment of the present invention is applied to an electronic lock 600. In FIG. 7, the electronic lock 600 has a latch bolt 610 extended outward to a locked position. When the piezoceramic/steel sheet assembly 400 of the actuator of the present invention is not supplied with a current, the second piezoceramic/steel sheet set 420 is in a fully straight state and the pin 510 does not interfere with the latch bolt 610, as shown in FIG. 5. That is, the actuator could not be externally operated to move the latch bolt 610 to an unlocked position, ensuring the electronic lock 600 is in a locked state.

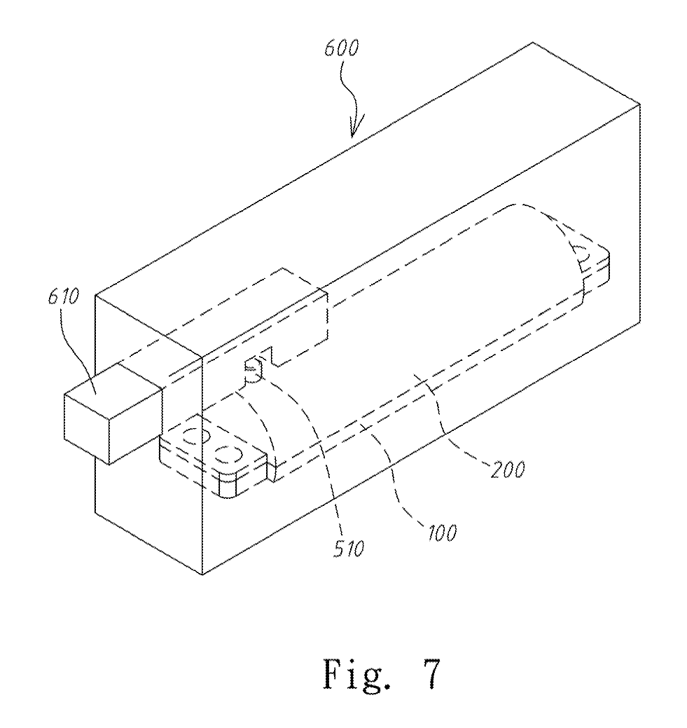

Please refer to FIGS. 6 and 7 at the same time. When the electronic lock 600 is in the locked state and a user wants to open it, the user may, for example, input a preset code as a user authentication procedure for the circuit board 300 to apply a voltage across the piezoceramic/steel sheet assembly 400. At this point, the first end portion 421 of the second piezoceramic/steel sheet set 420 in the free state is caused to flex upward and therefore displaces from the first end portion 411 of the first piezoceramic/steel sheet set 410, and the upward flexed first end portion 421 pushes against the pin 510 of the pin unit 500 for the shank 511 to protrude from the through bore 220, as shown in FIGS. 6 and 7. That is, the pin 510 interferes with the latch bolt 610 and is therefore able to actuate the latch bolt 610. For example, the actuator can be translated to move the latch bolt 610 into the unlocked position.

When the electronic lock 600 is in the locked state or when a user inputs incorrect code when trying to open the electronic lock 600, no current is supplied to the piezoceramic/steel sheet assembly 400, bringing the second piezoceramic/steel sheet set 420 released from the current to return to the original straight state, and the spring 520 elastically pushes the pin 510 rearward into the through bore 220, as shown in FIG. 5. That is, the pin 510 no longer interferes with the latch bolt 610, and the electronic lock 600 remains in the locked state to ensure the security provided by the electronic lock 600.

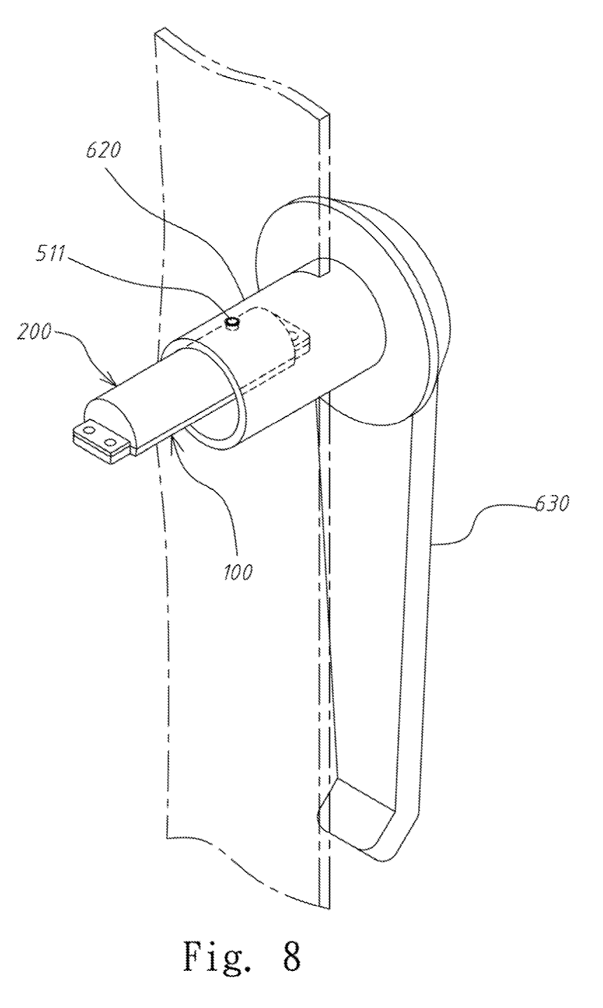

FIG. 8 shows the actuator according to the preferred embodiment of the present invention is applied to another differently operated electronic lock. In FIG. 8, the illustrated electronic lock is a general electronic door lock having a turnable element 620 connected to a door handle 630, and the actuator of the present invention having a relatively small volume is directly mounted in a core of the electronic door lock. When a current is supplied to the actuator, the shank 511 of the pin 510 is protruded from the second case 200 to couple with the rotatable element 620. When the door handle 630 is rotated, the actuator is brought to rotate at the same time to thereby actuate a latch bolt (not shown) of the electronic door lock to an unlocked position. On the other hand, when the electronic door lock is in a locked state or when a user inputs incorrect code when trying to open the electronic door lock, the shank 511 of the pin 510 fails to protrude from the second case 200 to couple with the rotatable element 620, and the door handle 630 idles when being turned, so that the electronic door lock remains in the locked state to ensure the security provided by the electronic door lock.

In the low-power-consumption actuator for battery-powered electronic lock according to the present invention, the piezoceramic/steel sheet assembly serves as a main displacement element and has the advantages of generating stable displacement and having only low power consumption, and requires only a DC working voltage as low as 3˜6.8V and a DC working current smaller than 15 mA. With the actuator of the present invention, a user needs only to replace the batteries of the electronic lock once a year, while the existing home electronic locks using a motor or a solenoid and requiring four 1.5V batteries has to replace the batteries once a month. The low-power-consumption actuator of the present invention is not only economical for use, but also friendly to people's living environment. The actuator of the present invention also has a service life more than 5 times as long as a motor, and can be turned on or off at least 200,000 times for operation with maximum operating times of one million. Further, since the actuator of the present invention uses the sheet-shaped piezoceramic/steel sheet assembly to replace the bulky coils, the actuator can be reduced in dimensions to meet the requirements for low profile and miniaturization. The actuator according to the present invention can have a size as small as 16 mm in width and 12 mm in height. Moreover, unlike a motor, the actuator of the present invention does not produce noise during operation thereof.

The present invention has been described with a preferred embodiment thereof and it is understood that many changes and modifications in the described embodiment can be carried out without departing from the scope and the spirit of the invention that is intended to be limited only by the appended claims.

What is claimed is:

1. A low-power-consumption actuator for battery-powered electronic lock, comprising:
a first case;
a second case being assembled to the first case to define a receiving space between the first and the second case, and being provided on a top with a through bore;
a piezoceramic/steel sheet assembly being arranged in the receiving space, and including two superposed first and second piezoceramic/steel sheet sets; the first piezoceramic/steel sheet set including two opposing first and second end portions, and the first end portion being fixed to an inner wall surface of the first case; the second piezoceramic/steel sheet set being located on one face of the first piezoceramic/steel sheet set facing toward the second case, and including two opposing first and second end portions; the second end portion of the second piezoceramic/steel sheet set being connected to the second end portion of the first piezoceramic/steel sheet set, and the first end portion of the second piezoceramic/steel sheet set being separated from the first end portion of the first piezoceramic/steel sheet set;
a circuit board being arranged in the receiving space and fixed to an inner wall surface of the second case, and being electrically connected to the piezoceramic/steel sheet assembly; and
a pin unit including a pin and a spring fitted around the pin; the pin being located atop the first end portion of the second piezoceramic/steel sheet set to align with the through bore on the second case; the pin including a shank and an expanded head integrally formed at one end of the shank; and the spring being fitted around the shank of the pin to locate between the expanded head of the pin and an area of the inner wall surface of the second case around a bottom of the through bore.

2. The low-power-consumption actuator for battery-powered electronic lock as claimed in claim 1, wherein the first case and the second case in an assembled state defines a semi-cylindrical housing.

3. The low-power-consumption actuator for battery-powered electronic lock as claimed in claim 1, wherein the first piezoceramic/steel sheet set includes stacked first steel sheet, first ceramic layer, and first electrically conductive metal layer; and the second piezoceramic/steel sheet set includes stacked second steel sheet, second ceramic layer, and second electrically conductive metal layer; and the circuit board being electrically connected to the first and second steel sheets and the first and second conductive metal layers.

4. The low-power-consumption actuator for battery-powered electronic lock as claimed in claim 3, wherein the first and the second ceramic layer are formed on one face of the first and the second steel sheet, respectively, by directly applying a ceramic material on the steel sheets.

5. The low-power-consumption actuator for battery-powered electronic lock as claimed in claim 3, wherein the first and the second the ceramic layer are formed on one face of the first and the second steel sheet, respectively, by gluing a sheet-shaped ceramic material to the steel sheets.

6. The low-power-consumption actuator for battery-powered electronic lock as claimed in claim 3, wherein the first and the second conductive metal layer are copper foil glued to one face of the first and the second ceramic layer opposite to the first and the second steel sheet, respectively, using a conducting paste.

7. The low-power-consumption actuator for battery-powered electronic lock as claimed in claim 3, wherein areas of the first conductive metal layer and the second conductive metal layer at the second end portions of the first and the second piezoceramic/steel sheet set, respectively, are bent to connect to each other and thereby form a wrapped end section of the piezoceramic/steel sheet assembly; and an insulating layer being provided between the wrapped end section and the first and second steel sheets at the second end portions.

8. The low-power-consumption actuator for battery-powered electronic lock as claimed in claim 3, wherein the second steel sheet is welded at the second end portion of the second piezoceramic/steel sheet set to the first steel sheet at the second end portion of the first piezoceramic/steel sheet set.

9. The low-power-consumption actuator for battery-powered electronic lock as claimed in claim 8, wherein the second steel sheet at the second end portion of the second piezoceramic/steel sheet set is provided at two lateral sides with a pair of second lugs, and the first steel sheet at the second end portion of the first piezoceramic/steel sheet set is provided at two lateral sides with a pair of first lugs corresponding to the pair of second lugs; and the first and the second steel sheet being welded together at the first and the second lugs.

10. The low-power-consumption actuator for battery-powered electronic lock as claimed in claim 3, wherein the second case is provided on a wall thereof at a predetermined position with a notch that extends through the wall of the second case for a power cord to extend through the notch into the receiving space to electrically connect to the circuit board.

11. The low-power-consumption actuator for battery-powered electronic lock as claimed in claim 3, wherein the piezoceramic/steel sheet assembly requires a DC working voltage as low as 3V and a DC working current as small as 10 mA; and wherein the first end portion of the second piezoceramic/steel sheet set has a displacement larger than 3 mm.
